(19) United States
(12) Patent Application Publication
(10) Pub. No.: US 2026/0333781 A1
(43) Pub. Date: Oct. 22, 2026

(54) JFET HAVING A LATERAL CHANNEL

(71) Applicant: Microchip Technology Incorporated, Chandler, AZ (US)

(72) Inventor: Shesh Mani Pandey, Gilbert, AZ (US)

(73) Assignee: Microchip Technology Incorporated, Chandler, AZ (US)

(21) Appl. No.: 19/644,859

(22) Filed: Apr. 10, 2026

Related U.S. Application Data
(60) Provisional application No. 63/791,892, filed on Apr. 21, 2025.

(51) Int. Cl. H10D 30/83; H10D 30/01; H10D 62/17

(52) U.S. Cl. CPC H10D 30/831; H10D 30/0515; H10D 62/343

(57) ABSTRACT

A junction field-effect transistor (JFET) may include a volume of semiconductor material that presents a top, an opposite bottom, a first side, and an opposite second side. The JFET may include laterally spaced first and second gates. A source may be positioned adjacent the top of the volume of semiconductor material, with the source being at least in part laterally between the first and second gates. A drain may be spaced apart from the source, with a channel being defined therebetween. The first gate may include a lateral gate portion extending laterally to underlie the source and at least a portion of the second gate, the lateral gate portion causing the channel to include a lateral channel portion defined between the lateral gate portion and the second gate.

### RELATED APPLICATION

The present U.S. non-provisional patent application is related to and claims priority benefit of an earlier-filed U.S. provisional patent application Ser. No. 63/791,892 filed Apr. 21, 2025. The entire content of the identified earlier-filed application is incorporated by reference as if fully set forth herein.

### TECHNICAL FIELD

The present disclosure relates to field-effect transistors (FETs) and methods of making them. More particularly, the various examples described herein are directed toward junction field-effect transistors (JFETs) having a lateral channel (or channel portion).

### BACKGROUND

A JFET is an active, voltage-controlled semiconductor device, in which varying electrical voltage between a gate and a source controls an electrical current flowing through a semiconductor channel between a drain and the source. Applications for JFETs include amplifiers, switches, resistors, regulators, power supplies, oscillators, choppers, and more. It is generally desirable to improve the performance and to reduce the cost of JFETs, but it can be difficult to do so.

This background discussion is intended to provide information related to the present disclosure, which is not necessarily prior art.

### SUMMARY

According to examples of the present disclosure, a semiconductor device, such as a JFET, includes a volume of semiconductor material including a top, an opposite bottom spaced from the top, a first side, and an opposite second side spaced from the first side. The JFET includes a first gate, a second gate spaced laterally from the first gate, a source positioned adjacent the top and at least in part laterally between the first and second gates, and a drain spaced apart from the source to define a channel therebetween. The first gate includes a lateral gate portion extending laterally to underlie the source and at least a portion of the second gate. The lateral gate portion causes the channel to include a lateral channel portion defined between the lateral gate portion and the second gate.

Various other examples include a method(s) of manufacturing and forming the example JFETs described herein.

This summary is not intended to identify essential features of the examples, and is not intended to be used to limit the scope of the claims. These and other aspects of the present examples are described below in greater detail.

### BRIEF DESCRIPTION OF THE DRAWINGS

Examples are described in detail below with reference to the attached drawing figures, wherein:

FIG. 1 illustrates an example JFET having a lateral channel, in accordance with the present disclosure;

FIG. 2 illustrates an example method of forming JFET having a lateral channel, in accordance with the present disclosure;

FIG. 3a illustrates an intermediate operation of the method of FIG. 2, in accordance with the present disclosure;

FIG. 3b illustrates an additional intermediate operation of the method of FIG. 2, in accordance with the present disclosure;

FIG. 3c illustrates an additional intermediate operation of the method of FIG. 2, in accordance with the present disclosure;

FIG. 3d illustrates an additional intermediate operation of the method of FIG. 2, in accordance with the present disclosure;

FIG. 3e illustrates an additional intermediate operation of the method of FIG. 2, in accordance with the present disclosure; and

The figures are not intended to limit the examples to the specific details illustrated therein. The drawings are not necessarily to scale.

### DETAILED DESCRIPTION

In the following detailed description, reference is made to the accompanying drawings, which form a part hereof and in which are shown, by way of illustration, specific examples in which the present disclosure may be practiced. These examples are described in sufficient detail to enable a person of ordinary skill in the art to practice the present disclosure. However, other examples may be utilized, and structural, material, and process changes may be made without departing from the scope of the disclosure. Unless clearly understood or expressly identified otherwise, structures, materials, procedures, operations, and other aspects described in the context of one example may be incorporated into other examples.

The illustrations presented herein are not meant to be actual views of any particular method, system, device, or structure, but are merely idealized representations that are employed to describe the examples of the present disclosure. The drawings presented herein are not necessarily drawn to scale. Similar structures or components in the various drawings may retain the same or similar numbering for the convenience of the reader; however, the similarity in numbering does not mean that the structures or components are necessarily identical in size, composition, configuration, or any other property.

Terms of relative location and direction (e.g., above, below, left, right, upper, lower, vertical, lateral, horizontal) may be used to facilitate the present descriptions of examples with reference to the figures, but unless clearly understood or expressly identified otherwise, these terms are not meant to be limiting with regard to location, direction, or overall orientation, and may, for example, change as a result of a change in overall orientation.

The following description may include examples to help enable one of ordinary skill in the art to practice the disclosed examples. The use of the terms “exemplary,” “by example,” and “for example,” means that the related description is explanatory, and though the scope of the disclosure is intended to encompass the examples and legal equivalents, the use of such terms is not intended to limit the scope of an example or this disclosure to the specified components, operations, features, functions, or the like.

It will be readily understood that the components of the examples as generally described herein and illustrated in the drawings could be arranged and designed in a wide variety of different configurations. Thus, the following description of various examples is not intended to limit the scope of the present disclosure but is merely representative of various examples.

The term “signal” or “electronic signal” may be used to describe electrical energy conducted through an electrically conductive medium in which an electric voltage and/or an electric current varies, or may be constant, over time. An electronic signal may be an electromagnetic wave, voltage, and/or current, and may be encoded with or representative of information.

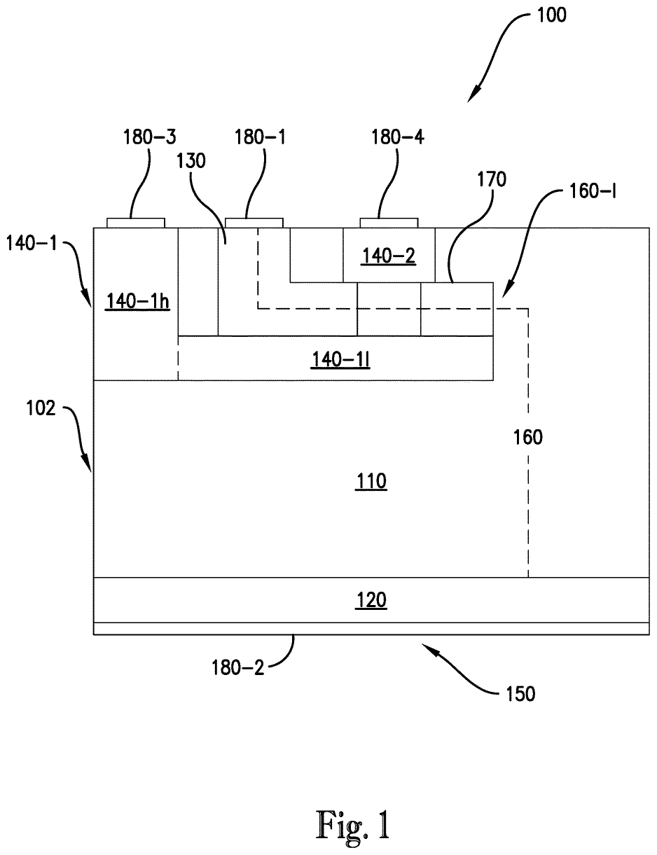

FIG. 1 illustrates a cross section of a JFET 100 having a channel 160 that includes a lateral channel segment 160-l, in accordance with the present disclosure. The JFET 100 may comprise, or otherwise be formed at least in part from, a volume of semiconductor material 102.

The JFET 100 further includes a drift region 110, a substrate 120, a source (or source region) 130, a first gate (or gate region) 140-1, a second gate (or gate region) 140-2, a drain 150, a doped region 170, and electrical contacts (or terminals) 180-1, 180-2, 180-3, 180-4. According to the present disclosure, the top of the volume of semiconductor material 102 is planar and at least a portion of the first and second gates 140-1, 140-2 and the source 130 are positioned, or formed, at and extend from at least the top of the volume of semiconductor material. However, it is within the ambit of certain principles of the example JFET 100 for one or more of the transistor components (source 130 and gates 140-1, 140-2) to be adjacent to (rather than at) or otherwise spaced from the top end of the volume of semiconductor material 102.

The volume of semiconductor material 102 includes: a top, an opposite bottom spaced (e.g., vertically) from the top, a first side, and an opposite second side spaced (e.g., horizontally or laterally) from the first side. As originally formed (to be explained further below), the volume of semiconductor material 102 may comprise, or be formed from, an N-type material. According to the present disclosure, the volume of semiconductor material 102 may be epitaxially grown, or formed via any other suitable means. In some examples, the volume of semiconductor material 102 may be pre-formed.

The volume of semiconductor material 102 may include, or be formed on, the substrate 120. The substrate 120 is positioned at, or adjacent to, the bottom of the volume of semiconductor material 102. The substrate 120 comprises, or is formed from, an N+material. The substrate 120 may be pre-formed, or, for instance, epitaxially grown.

According to various examples of the present disclosure, the drift region 110 includes at least the portion of the volume of semiconductor material 102 that generally defines the channel 160. In the illustrated example, the drift region 110 further includes any portion of the volume of semiconductor material outside the gates 140-1, 140-2, source 130, and doped region 170 (and drain 150 if the substrate 120 is considered or forms part of the volume of semiconductor material 102). The drift region may comprise, or be formed from, an N-type material.

The source 130 is positioned, or formed, at or adjacent to the top and at least in part laterally between first and second gates 140-1, 140-2. In the illustrated example, the source comprises, or is formed from, an N+ material. As illustrated in FIG. 1, the illustrated source 130 is roughly “L-shaped,” comprising a vertically extending portion and a laterally extending portion. The vertically extending portion may extend downwardly from the top of the volume of semiconductor material to contact a laterally extending portion 140-1l of the first gate 140-1. The laterally extending source portion may extend from the vertically extending source portion toward the second side of the volume of semiconductor material. More particularly, in the illustrated example, the laterally extending source portion is spaced from the top of the volume of semiconductor material 102, extends alongside and in contact with the lateral first gate portion 140-1l (described further below), and contacts and underlies part of the second gate 140-2. The endmost or rightmost terminal end portion of the source 130 spans between the first and second gates 140-1 and 140-2. However, according to some examples, the source may be alternatively constructed. As an example, certain aspects of the example JFET 100 contemplate a source with no lateral portion, such that just a vertical source portion, which may or may not extend downwardly into contact with the first gate lateral portion 140-1l, is provided. The vertical source portion may alternatively fill all or part of the space between the source and the vertically extending gate portion 140-1h (further described below) and/or all or part of the space between the source and the second gate 140-2. Certain examples of the JFET 100 also contemplate alternative shapes, configurations, and sizes of the lateral source portion. For instance, according to some examples, the lateral source portion may be spaced from the laterally extending gate portion 140-1l. Further, it is within the ambit of certain examples for the source to not contact the second gate 140-2, underlie more of the second gate than illustrated, or extend even closer to the second side of the volume of semiconductor material than the second gate and/or the first gate (in which case the doped region 170 may be eliminated or repositioned).

The first gate 140-1 is formed, or positioned, adjacent to the first side of the volume of semiconductor material 102. The second gate 140-2 is formed, or positioned, adjacent to the second side of the volume of semiconductor material 102. Broadly, the illustrated first and second gates 140-1, 140-2 comprise, or are formed from a P-type material. In various examples of the present disclosure, one or more portions of the first and/or second gates 140-1, 140-2 may be formed from materials of varying dopant concentrations.

For instance, the illustrated first gate 140-1, comprises two portions-vertically extending gate portion 140-1h and laterally extending gate portion 140-11. According to the present disclosure, the vertically extending gate portion 140-1h is defined by a dopant concentration that is relatively heavier, or higher, than the laterally extending gate portion 140-1l. Therefore, the vertically extending gate portion 140-1h may also be referred to as “the heavily, or highly, doped portion 140-1h” of first gate 140-1. Conversely, as a result of being defined by a relatively lighter, or lower, dopant concentration, the laterally extending gate portion140-1l may be referred to as “the lightly, or low, doped portion 140-1l” of the first gate 140-1.

The dashed line within the first gate 140-1 illustrated in FIG. 1 is meant purely as a visual aid to help delineate between the heavily and lightly doped portions 140-1h and 140-1l, respectively, of the first gate 140-1. The heavily doped portion 140-1h of the first gate 140-1 may comprise, or be formed from, a P+ material while the lightly doped portion 140-1l comprises, or is formed from, a P-type material. The second gate 140-2 may comprise, or be formed from, a P+ material.

In various examples, the dopant concentration of the highly doped gate portion 140-1h may be substantially similar or identical to the dopant concentration of the second gate 140-2, and greater than the dopant concentration of the lightly doped gate portion 140-1l. In certain alternative examples, both portions 140-1h, 140-1l of the first gate 140-1 may have or share a substantially similar or identical dopant concentration. For instance, the dopant concentration of both portions 140-1h, 140-1l of the first gate 140-1 may comprise, or be formed from a P+material, which may optionally have a substantially similar or identical dopant concentration to the P+material comprising the second gate 140-2.

In addition to extending from the top of the volume of semiconductor material 102, the heavily doped portion 140-1h of the first gate 140-1 is at (or alternatively adjacent to) the first side of the volume of semiconductor material 102. As illustrated in FIG. 1, the lightly doped gate portion 140-1l extends, or projects, laterally from the heavily doped gate portion 140-1h toward the second side of JFET 100. The lateral gate portion 140-1 l underlies the entirety of source 130, second gate 140-2, and doped region 170. However, according to some examples, the lateral gate portion 140-1l may underlie the source 130 and none or only part of the second gate 140-2. Furthermore, in examples where the doped region 170 is included in the FET and is spaced from the source 130, the lateral gate portion 140-1l underlies at least enough of the second gate 140-2 so that at least part of the doped region 170 spans between the gates.

The source 130 and drain 150 are positioned (or formed) at the top and bottom of the volume of semiconductor material 102, respectively. Despite the source 130 and drain 150 being vertically opposed to one another, the channel 160 extending therebetween includes at least one lateral portion 160-l. More particularly, the laterally extending portion 140-1l of the first gate 140-1 introduces the lateral channel portion 160-l into the channel 160. As illustrated in FIG. 1, there is at least one additional vertical channel segment extending from the lateral channel portion 160-l, such that the channel 160 turns vertically down toward the drain 150. According to certain aspects, the drain may alternatively be positioned at the top of the volume of semiconductor material 102, in which case the vertical portion of the channel 160 would be eliminated. Returning to the illustrated example, control of the channel 160 occurs generally along the lateral channel portion 160-1, between the lateral gate portion 140-1l and the second gate 140-2.

The doped region 170 is formed along the lateral channel portion 160-1, alongside the lateral gate portion 140-1l of the first gate 140-1. The doped region 170 makes contact with at least a portion of the lightly doped portion 140-1l of the first gate 140-1 and the second gate 140-2. In the illustrated example, the doped region 170 comprises, or is formed from, an N+ material. The doped region 170 spans between the lateral gate portion 140-1l and the second gate 140-2, although certain alternative examples contemplate the doped region being spaced from one or both of the lateral gate portion and the second gate. The doped region 170 is spaced apart from the source 130 such that a portion of drift region 110 is located therebetween. The portion of the drift region 110 located between doped region 170 and source 130 may be further defined (in a vertical direction) by the lateral portion 140-1l of the first gate 140-1 and the second gate 140-2.

The doped region 170 may comprise, or be formed from, an N-type material having a greater dopant concentration than the drift region 110. In the illustrated embodiment, the doped region 170 may comprise, or be formed from, an N+ material having a substantially similar or identical dopant concentration as the N+ material comprising the source 130. In various other examples, the dopant concentration of the material comprising the source 130 may be greater than the dopant concentration of the material comprising the doped region 170 (e.g., the source 130 may be formed from a N++ material while the doped region is formed from a N+ material).

In various examples of the present disclosure, a right edge, or margin of the doped region 170 and a right edge, or margin, of the laterally extending portion 140-1l of the first gate 140-1 are spaced equidistantly from the second side of the volume of semiconductor material 102. It will be appreciated, however, that certain alternative examples contemplate the lateral gate portion 140-1l and doped region 170 to be spaced unequally from the second side of the volume of semiconductor material 102. The spacing of the right edge, or margin, of the second gate 140-2 may similarly be varied, according to some aspects of the example JFET 100. Although not shown, such alternative examples may involve extending the second gate 140-2 and the doped region 170 all the way to the second side of the volume of semiconductor material. Further, in other alternative examples, the doped region 170 may be spaced from the second side of the volume of semiconductor material 102 but not extend closer to the second side of the volume of semiconductor material than the second gate 140-2. In such an alternative example, the lateral gate portion 140-1l of the first gate 140-1, the second gate 140-2, and the doped region 170 may all be equally spaced from the second side of the volume of semiconductor material 102.

The shape, size, and material composition of the doped region 170 formed within JFET 100 may vary.

The JFET 100 may include electrical terminals, or contacts, 180-1, 158-2, 150-3, and 180-4 to facilitate the application of various electrical signals thereto. As illustrated in FIG. 1, the first electrical terminal 180-1 may be added to, or formed on, the source 130. The second electrical terminal 180-2 may be applied to, or formed on, the drain 150. The third electrical terminal 180-3 may be applied to, or formed on, or over, the first gate 140-1, and more particularly, the highly doped portion 140-1h of the first gate 140-1 (with the low doped portion 140-1l of the first gate 140-1 being spaced from third terminal 180-3). The fourth electrical terminal 180-4 may be applied to, or formed on, or over, the second gate 140-2. It will be appreciated that the third and fourth electrical terminals 180-3, 180-4 may be independent, electrically isolated terminals, or may alternatively be portions of a single, electrically continuous terminal (such that the gates 140-1, 140-2 are shorted).

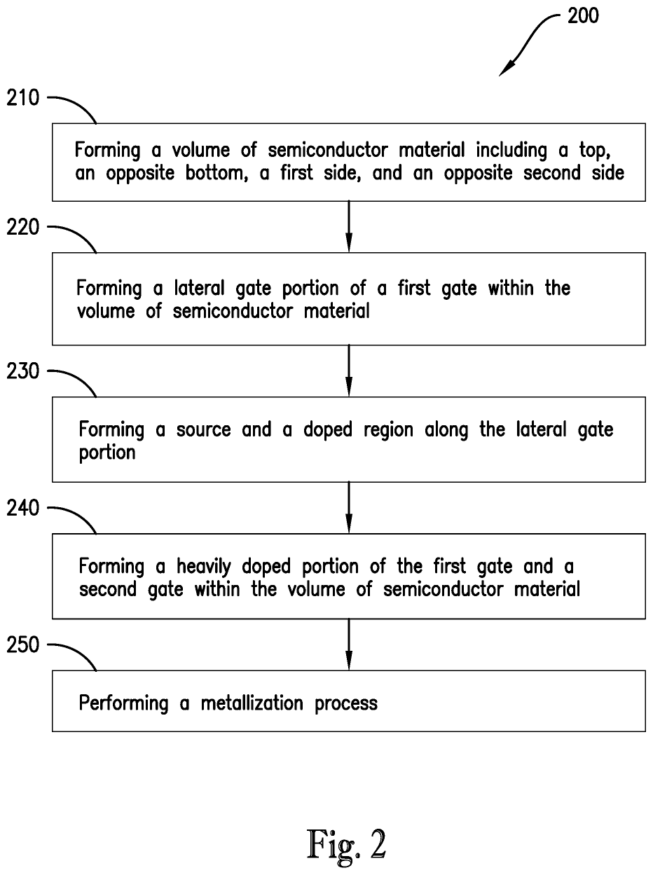

FIG. 2 illustrates a method 200 for forming a JFET in accordance with the present disclosure.

Broadly, any feature, portion, area, or volume (doped or undoped) of a JFET or any other semiconductor device formed by the method 200 may be formed via any process suitable for forming said feature(s), portion(s), area(s), or volume(s). For instance, ion implantation and other similar/suitable processes may be used to form wells, sources, bodies, and the like, without limitation. Epitaxial growth and similar/suitable processes may be used to form substrates and initial, intermediate, or precursor volumes of semiconductor material. Etching and other similar/suitable processes may be used to remove select portions of semiconductor material once formed (e.g., to form a trench within a volume(s) of semiconductor material), or to remove portions of oxide, metal, or metal alloy layers, without limitation. Deposition and other similar/suitable processes may be used to fill trenches once etched, to form electrical terminals (or contacts), and the like, without limitation.

Performance of the method 200 may, at various stages throughout, result in formation of an intermediate, or precursor, volume of semiconductor material, which in turn, may be formed into a JFET in accordance with the present disclosure.

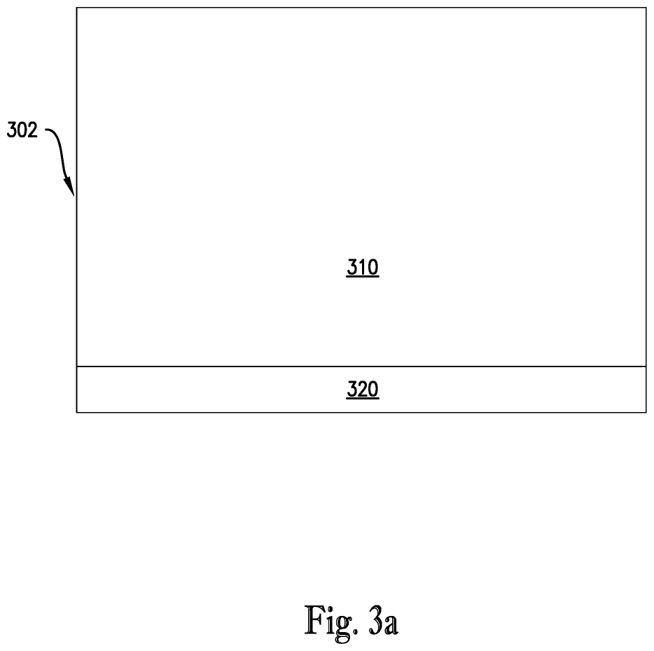

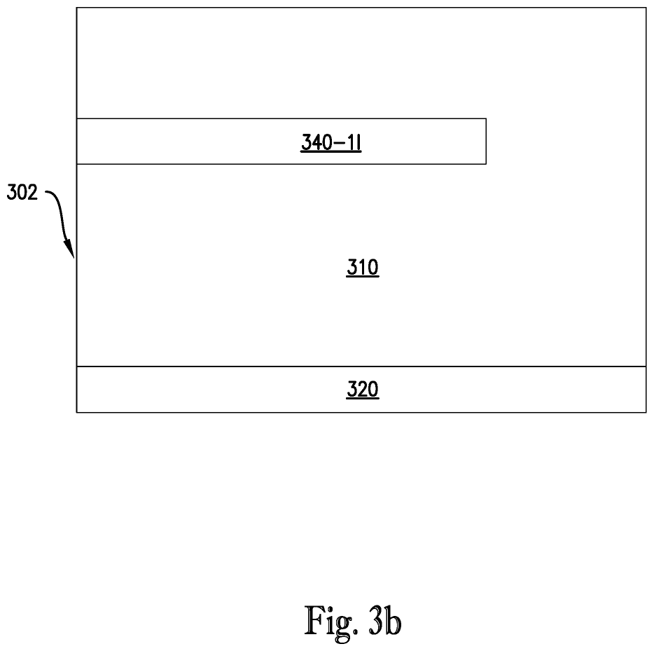

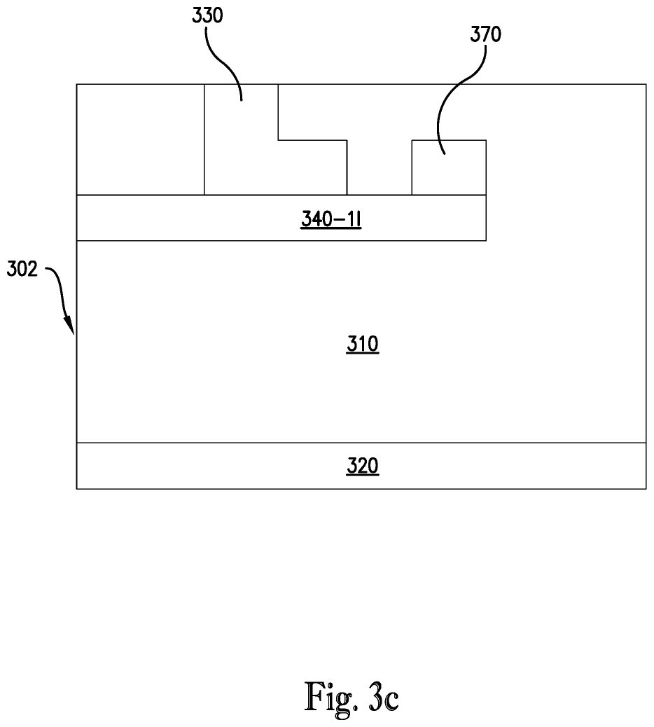

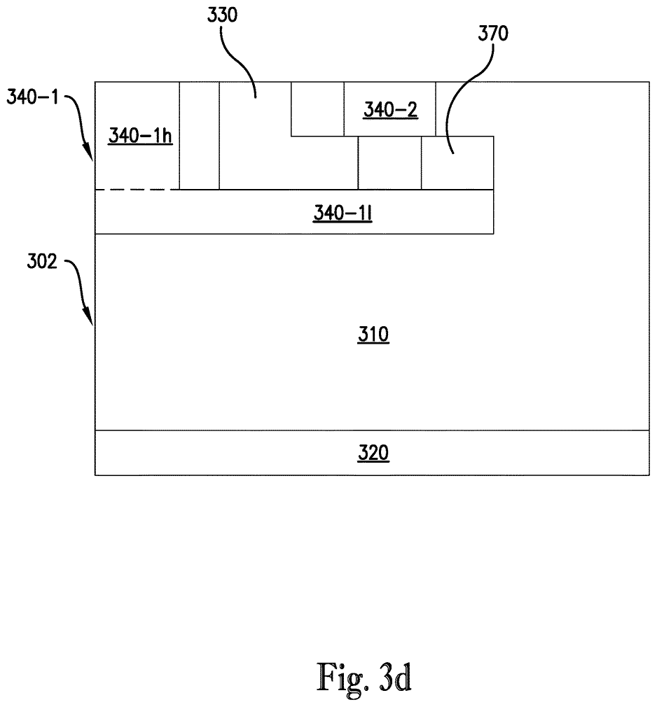

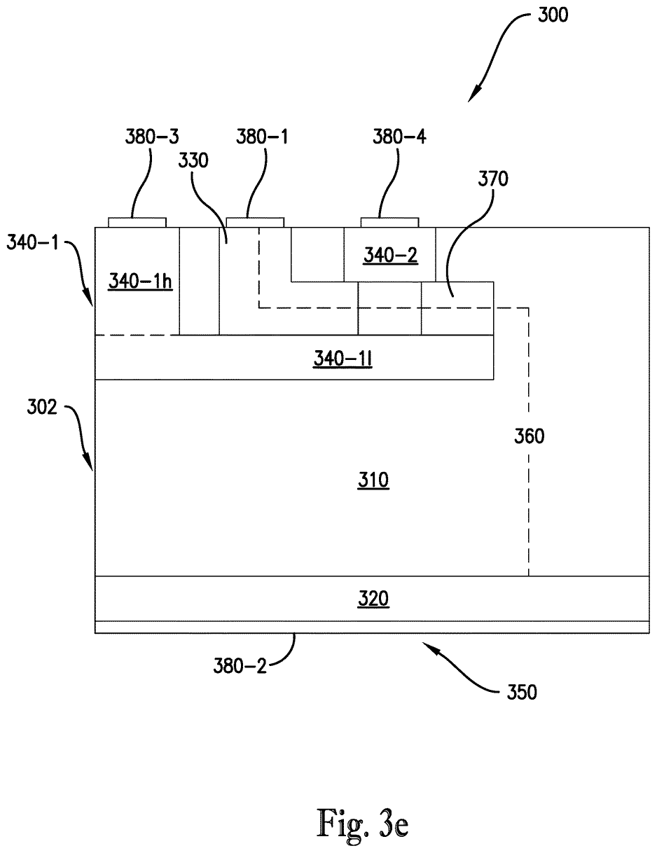

FIGS. 3a-3e collectively illustrate cross-sections of a JFET 300, which may be substantially similar or identical to the JFET 100 of FIG. 1. Accordingly, each feature, region, and/or sub-region included in JFET 300 may be substantially similar or identical to the corresponding feature, region, and/or sub-region of JFET 100. For instance, source 330 may be substantially similar or identical to source 130, substrate 320 may be substantially similar or identical to substrate 120, electrical terminal 380-2 may be substantially similar or identical to electrical terminal 180-2, and so on, without limitation. Accordingly, for the sake of brevity, redundant description of features, regions, and/or sub-regions common to JFETs 100, 300 have been greatly reduced, if not eliminated, herein.

The cross-sections of the JFET 300 illustrated in FIGS. 3a-3e illustrate progress in the formation of the JFET 300 at various, intermediate points in time throughout the performance of the method 200. Accordingly, the intermediate cross-sections illustrated in FIGS. 3a-3e may be referenced alongside discussion of the operations of the method 200.

Referring to FIG. 2, operation 210 may include forming, or otherwise providing, a volume of semiconductor material 302 having a top, an opposite bottom, a first side, and an opposite second side. The top is spaced vertically and upwardly from the bottom end, and the left side is spaced laterally from the right side. The volume of semiconductor material 302 may be formed on (e.g., by epitaxial growth), or include, a substrate 320. The substrate may be pre-formed. Referring to FIG. 3a, the substrate may comprise, or be formed from, an N+ material, and the remainder 310 of the volume of semiconductor material 302 may comprise, or be formed from, a N-type material. A significant portion of the volume of semiconductor material forms a drift region 310, along which at least part of the channel is formed, as further described herein. The volume of semiconductor material 302 may be formed on, along, or adjacent to the substrate 320.

FIG. 3b illustrates the implantation of a laterally extending, P-type region within the N-type volume of semiconductor material 302 during operation 220. It will be appreciated that the P-type region generally forms, or will form, the laterally extending and lightly doped portion 340-1l of first gate 340-1. As above, the laterally extending portion 340-1l of first gate 340-1 is defined by its relatively lighter, or lower, dopant concentration when compared to the vertically extending portion 340-1h of the first gate 340-1 that is more heavily doped. As noted previously, however, certain examples contemplate the laterally and vertically extending gate portions 340-1l, 340-1h to have the same dopant concentration. The fully formed first gate 340-1 (e.g., comprising both vertically and laterally extending portions 340-1h, 340-1l) can be seen in FIG. 3d, and will be described further below. Accordingly, the laterally extending doped portion 340-1l of the first gate 340-1 may also be referred to as “the lightly doped portion 340-1l” and the vertically extending region 340-1h of the first gate 340-1 may be referred as the heavily, or highly, doped portion 340-1h.

FIG. 3c illustrates a source, or source region 330 and a doped region 370 that are formed from a N+ material during operation 230. As above, a portion of the source 330 and doped region 370 are spaced from the top of the volume of semiconductor 302 and contact lightly doped portion 340-1l of the first gate 340-1. Further, the source 330 includes a vertically extending portion and a laterally extending portion, with the vertically extending portion extending from the laterally extending portion to the top of the volume of semiconductor material 302.

At operation 240, a heavily doped portion 340-1h of first gate 340-1 and a second gate 340-2 are formed within the volume of semiconductor material 302. The heavily doped portion 340-1h and the second gate 340-2 may be formed concurrently, as first illustrated in FIG. 3d. The heavily doped portion 340-1h and the second gate 340-2 extend from the top of the volume of semiconductor material. The heavily doped portion 340-1h of the first gate 340-1 extends to make contact with the lightly doped portion 340-1l of the first gate 340-1. The second gate 340-2 extends to make contact with at least a portion of the source 330 (e.g., the laterally extending portion of the source 330) and the doped region 370. The heavily doped portion 340-1h and the second gate 340-2 may comprise, or be formed from a P+ material of substantially similar or identical dopant concentrations. The lightly doped portion 340-1l of the first gate may comprise, or be formed from, a P-type material having a dopant concentration that is, preferably, less than the dopant concentration of the heavily doped portion 340-1h and the second gate 340-2, although the dopant concentration of the of the lightly doped region 340-1l being substantially similar or identical to the dopant concentration of the heavily doped portion 340-1h and the second gate 340-2 does not depart from the present disclosure.

As previously described, a majority of the volume of semiconductor material 302 remains the drift region 310, along which at least part of the channel 360 is formed. The drift region 310 may be substantially similar or identical to the drift region 110 of JFET 100 of FIG. 1. More particularly, the drift region 310 may include any portion of the volume of semiconductor material outside the gates 340-1, 340-2, source 330, and doped region 370 (and the substrate 320 assuming such is considered or forms part of the volume of semiconductor material 302). The example JFET 300, with its components formed according to the foregoing operations, provides a portion of the drift region 310 interposed between source 330 and doped region 370. The doped region 370 is located along the lateral portion of the channel 360.

At operation 250, a metallization process is performed to form electrical contacts, or terminals, 380-1, 380-2, 380-3, and 380-4 that are formed on, or applied to, the source 330, drain 350, the highly doped portion 340-1h of the first gate 340-1, and the second gate 340-2, respectively. Formation of the electrical terminals 380-1 through 380-4 may facilitate application of electrical signals to the JFET 300, and result in the formation and/or modulation of channel 360 extending between source 330 and drain 350.

Additional details for each of the operations in the method 200 and/or corresponding to the intermediate steps of forming the JFET 300 can be found in connection with the descriptions of FIG. 1.

### Feature Combinations

According to various examples of the present disclosure, a junction field-effect transistor (JFET) may include a volume of semiconductor, a first gate, a second gate, a source, and a drain. The volume of semiconductor material may include a top, an opposite bottom spaced from the top, a first side, and an opposite second side spaced from the first side. The second gate is laterally spaced from the first gate. The source is positioned adjacent to the top and at least in part laterally between the first and second gates. The drain is spaced apart from the source to define a channel therebetween. The first gate may include a lateral gate portion extending laterally to underlie the source and at least a portion of the second gate. The lateral gate portion causes the channel to include a lateral channel portion defined between the lateral gate portion and the second gate.

In combination with the previous example, the drain may be located at the bottom of the volume of semiconductor material, and the channel may include a vertical channel portion that extends downwardly from the lateral channel portion to the drain.

In combination with any of the previous examples, the top of the volume of semiconductor material may be planar, and the first and second gates and the source may be positioned at the top of the volume of semiconductor material.

In combination with any of the previous examples, the first gate may include a high doped region and a low doped region, with the dopant concentration of the high doped region being greater than the lower doped region. The lateral gate portion of the first gate may be defined by the low dopant region.

In combination with any of the previous examples, a gate electrical terminal may contact the first gate, a high doped region of the first gate may be in contact with the gate electrical terminal, and a low doped region of the first gate may be spaced from the gate electrical terminal.

In combination with any of the previous examples, the first gate may be adjacent the first side of the volume of semiconductor material, and the second gate may be adjacent to the second side of the volume of semiconductor material. The lateral gate portion may project toward the second side of the volume of semiconductor material beyond the second gate.

In combination with any of the previous examples, the source may extend vertically to contact the lateral gate portion.

In combination with any of the previous examples, the source may include a lateral source portion that is spaced from the top of the volume of semiconductor material and extends laterally toward at least a portion of the lateral gate portion.

In combination with any of the previous examples, the lateral source portion may contact the second gate.

In combination with any of the previous examples, the lateral source portion may extend under part of the second gate.

In combination with any of the previous examples, a doped region may be positioned along the lateral channel portion.

In combination with any of the previous examples, the channel may be defined by a drift region of the volume of semiconductor material; a doped region, the source, and the drift region may have the same polarity; the doped region may have a dopant concentration that is greater than that of the drift region; and the doped region may span between the lateral gate portion and the second gate.

In combination with any of the previous examples, a doped region may be spaced from the source such that a portion of the drift region is located between the source and the doped region, and the portion of the drift region being defined between the lateral gate portion and the second gate.

In combination with any of the previous examples, the source may extend vertically to contact the lateral gate portion, and the source may contact the second gate.

In combination with any of the previous examples, the source may include a lateral source portion that is spaced from the top of the volume of semiconductor material and extends laterally alongside at least a portion of the lateral gate portion.

In combination with any of the previous examples, a source electrical terminal may contact the source. The source may include an upper portion extending between the source electrical terminal and a lateral source portion, and the upper portion of the source being spaced from the second gate.

In combination with any of the previous examples, the first gate may be adjacent the first side of the volume of semiconductor material and the second gate may be adjacent to the second side of the volume of semiconductor material. A doped region may be spaced from the second side of the volume of semiconductor material but extend closer to the second side of the volume of semiconductor material than the second gate.

In combination with any of the previous examples, the lateral gate portion and a doped region may be spaced equidistantly from the second side of the volume of semiconductor material.

In combination with any of the previous examples, the source may have a dopant concentration that is the same as a dopant concentration of a doped region.

In combination with any of the previous examples, the source may have a dopant concentration that is greater than a dopant concentration of a doped region.

### General Considerations

In this description, references to “one embodiment,” “an embodiment,” “embodiments,” “an example,” “one example,” or “examples” mean that the feature or features being referred to are included in at least one embodiment or example of the technology. Separate references to “one embodiment,” “an embodiment,” “embodiments,” “an example,” “one example,” or “examples” in this description do not necessarily refer to the same embodiment or example and are also not mutually exclusive unless so stated and/or except as will be readily apparent to those skilled in the art from the description. For example, a feature, structure, act, etc. described in one embodiment may also be included in other embodiments but is not necessarily included. Thus, the current technology can include a variety of combinations and/or integrations of the embodiments described herein.

Throughout this specification, plural instances may implement components, operations, or structures described as a single instance. Although individual operations of one or more methods are illustrated and described as separate operations, one or more of the individual operations may be performed concurrently, and nothing requires that the operations be performed in the order illustrated. Structures and functionality presented as separate components in example configurations may be implemented as a combined structure or component. Similarly, structures and functionality presented as a single component may be implemented as separate components. These and other variations, modifications, additions, and improvements fall within the scope of the subject matter herein, unless otherwise expressly stated and/or readily apparent to those skilled in the art from the description.

As used herein, the terms “comprises,” “comprising,” “includes,” “including,” “has,” “having” or any other variation thereof, are intended to cover a non-exclusive inclusion. For example, a process, method, article, or apparatus that comprises a list of elements is not necessarily limited to only those elements but may include other elements not expressly listed or inherent to such process, method, article, or apparatus. Further, unless expressly stated to the contrary, “or” refers to an inclusive or and not to an exclusive or. For example, a condition A or B is satisfied by any one of the following: A is true (or present) and B is false (or not present), A is false (or not present) and B is true (or present), and both A and B are true (or present).

The patent claims at the end of this patent application are not intended to be construed under 35 U.S.C. § 112(f) unless traditional means-plus-function language is expressly recited, such as “means for” or “step for” language being explicitly recited in the claim(s).

Although the invention has been described with reference to the embodiments illustrated in the attached drawing figures, it is noted that equivalents may be employed and substitutions made herein without departing from the scope of the invention as recited in the claims.

While the present disclosure has been described herein with respect to certain illustrated examples, those of ordinary skill in the art will recognize and appreciate that the present disclosure is not so limited. Rather, many additions, deletions, and modifications to the illustrated and described examples may be made without departing from the scope of the disclosure as hereinafter claimed along with their legal equivalents. In addition, features from one example may be combined with features of another example while still being encompassed within the scope of the disclosure as contemplated by the inventors.

Although described herein with regard or in relation to one or more particular kinds of electronic devices (e.g., junction field-effect transistor, metal oxide semiconductor field-effect transistor), the technology may be more broadly applicable to one or more other kinds of electronic devices as well.

One with ordinary skill in the art will recognize that the technology described herein may, when applicable, be implemented in enhancement mode or depletion mode.

Further, the technology described herein may, when applicable, be implemented as an N-channel or P-channel device, wherein, in general, regions that are N-doped or P-doped in N-channel implementations may be, respectively, P-doped or N-doped in P-channel implementations.

Additionally, the various example materials identified herein may, in some aspects, be replaced and/or supplemented with substantially any other suitable material. For example, gate material may include polysilicon, a metal or alloy of metals, or other suitable material; gate oxide or dielectric may include silicon dioxide (SiO₂), aluminum oxide (Al₂O₃), hafnium dioxide (HfO₂), silicon nitride (Si₃N₄), or other suitable material; and semiconductor material may include silicon carbide (SiC), gallium nitride (GaN), zinc oxide (ZnO), or other suitable material.

Additionally, in general, unless otherwise specified or unless one with ordinary skill in the art would understand otherwise, doping characterized as “++” (e.g., P++) will have a relatively higher concentration of dopants than “+” (e.g., P+) doping, “+” doping will have a relatively higher concentration than “-well” (e.g., P-well) doping, and “-well” doping will have a relatively higher concentration of doping than “−” (e.g., P−) doping. In general, doping concentrations (typically measured in parts-per-cubic-centimeter) for contact implants (e.g., sources, drains, body contacts) may be approximately between 5×10\hat{ }18 and 1×10\hat{ }22; doping concentrations for channel and threshold forming implants (e.g., P-wells) may be approximately between 5×10\hat{ }15 and 5×10\hat{ }17; doping concentrations for shielding implants may be approximately between 5×10\hat{ }17 and 5×10\hat{ }19; doping concentrations for conductivity improvement implants (e.g., N-doping in the junction field-effect transistor neck region of a metal oxide semiconductor field-effect transistor) may be approximately between 1×10\hat{ }17 and 1×10\hat{ }19; and doping concentrations for drift regions (e.g., N doping) may be approximately between 1×10\hat{ }15 and 1×10\hat{ }16. In some examples, the doping concentration range for the drift region may be widened, for example to approximately between 1×10\hat{ }14 and 1×10\hat{ }18.

Relatedly, a structure or region may contain two or more different doping doses. In various examples, dopant concentrations within a given structure or region may vary within the example range described above for the corresponding region type. Dopant concentration may vary according to a gradient that gradually decreases as the depth of the implant increases. Further, one with ordinary skill in the art will recognize that some P-wells may contain a lower dose P-well portion and a higher dose unclamped inductive switching portion. Dopant concentration variation within a given structure or region may result from normal manufacturing variance, may be by design, or may otherwise arise without departing from the spirit of the present disclosure.

Additionally, although only one or a few instances of a device or apparatus may be described herein, it will be appreciated that some applications may involve many such devices or apparatuses, which may be different from, substantially similar to, or identical to the described device or apparatus, and which may be arranged (e.g., in an array) on a larger extension of the volume of semiconductor material. In that light, references to a right and/or left side of a volume of semiconductor material may be to the conceptual limit of a particular unit cell and not to an actual physical end of the material.

1. A junction field-effect transistor (JFET) comprising:
a volume of semiconductor material including a top, an opposite bottom spaced from the top, a first side, and an opposite second side spaced from the first side;
a first gate;
a second gate spaced laterally from the first gate;
a source positioned adjacent the top and at least in part laterally between the first and second gates; and
a drain spaced apart from the source to define a channel therebetween,
the first gate including a lateral gate portion extending laterally to underlie the source and at least a portion of the second gate,
the lateral gate portion causing the channel to include a lateral channel portion defined between the lateral gate portion and the second gate.

2. The JFET of claim 1,
the drain being located at the bottom of the volume of semiconductor material,
the channel including a vertical channel portion that extends downwardly from the lateral channel portion to the drain.

3. The JFET of claim 1,
the top of the volume of semiconductor material being planar,
the first and second gates and the source being positioned at the top.

4. The JFET of claim 1,
the first gate including a high doped region and a low doped region, with the dopant concentration of the high doped region being greater than the low doped region,
the lateral gate portion being defined by the low doped region.

5. The JFET of claim 4, comprising:
a gate electrical terminal contacting the first gate,
the high doped region of the first gate being in contact with the gate electrical terminal,
the low doped region of the first gate being spaced from the gate electrical terminal.

6. The JFET of claim 1,
the first gate being adjacent the first side of the volume of semiconductor material, and the second gate being adjacent the second side of the volume of semiconductor material,
the lateral gate portion projecting toward the second side of the volume of semiconductor material beyond the second gate.

7. The JFET of claim 1,
the source extending vertically to contact the lateral gate portion.

8. The JFET of claim 7,
the source including a lateral source portion that is spaced from the top of the volume of semiconductor material and extends laterally alongside at least a portion of the lateral gate portion.

9. The JFET of claim 8,
the lateral source portion contacting the second gate.

10. The JFET of claim 9,
the lateral source portion extending under part of the second gate.

11. The JFET of claim 1, comprising:
a doped region positioned along the lateral channel portion.

12. The JFET of claim 11,
the channel being defined in part by a drift region of the volume of semiconductor material,
the doped region, source, and drift region having the same polarity,
the doped region having a dopant concentration that is greater than that of the drift region,
the doped region spanning between the lateral gate portion and the second gate.

13. The JFET of claim 12,
the doped region being spaced from the source such that a portion of the drift region is located between the source and the doped region,
the portion of the drift region being defined between the lateral gate portion and the second gate.

14. The JFET of claim 13,
the source extending vertically to contact the lateral gate portion,
the source contacting the second gate.

15. The JFET of claim 14,
the source including a lateral source portion that is spaced from the top of the volume of semiconductor material and extends laterally alongside at least a portion of the lateral gate portion.

16. The JFET of claim 15, comprising:
a source electrical terminal contacting the source,
the source including an upper portion extending between the source electrical terminal and the lateral source portion,
the upper portion of the source being spaced from the second gate.

17. The JFET of claim 13,
the first gate being adjacent the first side of the volume of semiconductor material, and the second gate being adjacent the second side of the volume of semiconductor material,
the doped region being spaced from the second side of the volume of semiconductor material but extending closer to the second side of the volume of semiconductor material than the second gate.

18. The JFET of claim 17,
the lateral gate portion and the doped region being spaced equidistantly from the second side of the volume of semiconductor material.

19. The JFET of claim 12,
the source having a dopant concentration that is the same as the dopant concentration of the doped region.

20. The JFET of claim 12,
the source having a dopant concentration that is greater than the dopant concentration of the doped region.
